(19) United States
(12) Patent Application Publication
(10) Pub. No.: US 2010/0301442 A1
(43) Pub. Date: Dec. 2, 2010

(54) OPTICAL SEMICONDUCTOR DEVICE

(76) Inventors: Takaki IWAI, Osaka (JP); Hironari TAKEHARA, Kyoto (JP)

Correspondence Address: MCDERMOTT WILL & EMERY LLP, 600 13TH STREET, NW, WASHINGTON, DC, 20005-3096, US

(21) Appl. No.: 12/755,147

(22) Filed: Apr. 6, 2010

(30) Foreign Application Priority Data
May 26, 2009 (JP) 2009-126113

(51) Int. Cl. H01L 31/118; H01L 31/0232; H01L 31/0224

(52) U.S. Cl. 257/437; 257/461; 257/E31.089; 257/E31.128; 257/E31.126

(57) ABSTRACT

An optical semiconductor device that performs photoelectric conversion, comprising: a semiconductor substrate that includes (i) a first conductivity-type semiconductor region, (ii) a second conductivity-type semiconductor region that is positioned on the first conductivity-type semiconductor region and has a light receiving surface, and (iii) a first conductivity-type contact region that penetrates, from an upper surface of the second conductivity-type semiconductor region, the second conductivity-type semiconductor region so as to be in contact with the first conductivity-type semiconductor region; an electrode pair for drawing current obtained by performing photoelectric conversion of light incident on the light receiving surface, the electrode pair being composed of (i) a first electrode that is positioned on the first conductivity-type contact region and (ii) a second electrode that is positioned on the second conductivity-type semiconductor region so as to be separated from the first electrode; an insulating film that is positioned on the second conductivity-type semiconductor region and in an area between the first electrode and the second electrode; and a third electrode that is positioned on the insulating film.

The disclosure of Japanese Patent Application No. 2009-126113 filed May 26, 2009 including specification, drawings and claims is incorporated herein by reference in its entirety.

### BACKGROUND OF THE INVENTION

(1) Field of the Invention

The present invention relates to an optical semiconductor device that includes a light receiving element, and especially to technology for reducing parasitic capacitance at a p-n junction.

(2) Description of the Related Art

Such an optical semiconductor device is used, for example, in an OEIC (Optical Electrical Integrated Circuit) that is used in an optical pickup device for reading/writing signals from/to an optical disc.

The following describes an example of a structure of a general optical semiconductor device used in the OEIC.

FIG. 11 is a cross-sectional view showing a structure of an optical semiconductor device 1000. By way of example, in FIG. 11, a p-type semiconductor substrate is illustrated as a semiconductor substrate, and a PIN photodiode is illustrated as a light receiving element.

The optical semiconductor device 1000 includes a highly concentrated p-type semiconductor substrate 1001, a low concentrated p-type semiconductor region 1002, an n-type semiconductor region 1003, a highly concentrated p-type element isolation region 1004, a highly concentrated n-type cathode region 1005, a LOCOS (Local Oxidation of Silicon) isolation region 1006, a field film 1007, a cathode electrode 1008, an anode electrode 1009, and an antireflection film 1010. The p-type semiconductor region 1002 is positioned on the p-type semiconductor substrate 1001. The n-type semiconductor region 1003 is positioned on the p-type semiconductor region 1002. The p-type element isolation region 1004 is selectively positioned, from an upper surface of the n-type semiconductor region 1003, so as to reach the p-type semiconductor region 1002. The n-type cathode region 1005 is selectively positioned on the n-type semiconductor region 1003. The LOCOS isolation region 1006 is selectively positioned on the n-type semiconductor region 1003. The field film 1007 is positioned on the n-type semiconductor region 1003 and the LOCOS isolation region 1006. The cathode electrode 1008 is selectively positioned on the n-type cathode region 1005. The anode electrode 1009 is positioned on the p-type element isolation region 1004. And the antireflection film 1010 is positioned on a light receiving surface that is formed by opening the field film 1007.

In the optical semiconductor device 1000 having the above structure, when a reverse bias is applied between the cathode electrode 1008 and the anode electrode 1009, a depletion region 1011 is formed in a junction area of the p-type semiconductor region 1002 and the n-type semiconductor region 1003. As shown in FIG. 11, however, the depletion region 1011 expands toward the p-type semiconductor region 1002 because the p-type semiconductor region 1002 has lower concentration of impurities than the n-type semiconductor region 1003.

As a speed at which a playback device plays back an optical disc has increased, a photodiode speed is hoped to be further increased. Here, since frequency characteristics of a photodiode are inversely proportional to the CR product, which is the product of parasitic capacitance and a parasitic resistance of the photodiode, it is important to reduce the parasitic capacitance.

In general, junction capacitance at the p-n junction is the most dominant as the parasitic capacitance that can prevent the increase in speed. Therefore, in the above-mentioned example, an attempt is made to increase the photodiode speed by reducing the junction capacitance at the p-n junction. Specifically, since the parasitic capacitance at the p-n junction is inversely proportional to a width of a depletion region, in the optical semiconductor device 1000, the depletion region is expanded and the region is completely depleted by decreasing concentration of impurities (e.g. 10¹⁵ cm⁻³ or less) in the p-type semiconductor region 1002.

Besides the junction capacitance in a junction area of the p-type semiconductor region 1002 and the n-type semiconductor region 1003 (bottom capacitance), however, junction capacitance in a junction area of the p-type element isolation region 1004 and the n-type semiconductor region 1003 (side capacitance) is also included in the junction capacitance at the p-n junction. Since the p-type element isolation region 1004 has higher concentration of impurities than the n-type semiconductor region 1003, the side capacitance becomes larger than the bottom capacitance, per unit area. Accordingly, when a photodiode has, for example, a rectangular shape with a large perimeter, the side capacitance is increased and can prevent the increase in speed.

To solve the problem, in an optical semiconductor device 2000 disclosed in Japanese Patent Application Publication No. 2008-117952, an attempt is made to reduce the side capacitance of the photodiode by forming a depletion region also in a junction area of the p-type element isolation region 1004 and the n-type semiconductor region 1003. The following describes the optical semiconductor device 2000 in more detail.

FIG. 12 is a cross-sectional view showing a structure of an optical semiconductor device 2000. In addition to the structures of the optical semiconductor device 1000 shown in FIG. 11, the optical semiconductor device 2000 further includes a plurality of highly concentrated p-type semiconductor regions 2001. Each of the p-type semiconductor regions 2001 is positioned between the n-type semiconductor region 1003 and the p-type element isolation region 1004.

In the optical semiconductor device 2000, the plurality of p-type semiconductor regions 2001 are positioned with regularity in an in-plane direction of the n-type semiconductor region 1003, and electrically connected to the p-type element isolation region 1004 via the low concentrated p-type semiconductor region 1002.

With this structure, depletion regions are formed inside the p-type semiconductor regions 2001 and in the neighboring region due to application of reverse voltage between the cathode electrode 1008 and the anode electrode 1009. Then the depletion regions unite with each other, and the depletion region 1011 in which the depletion regions unite in an in-plane direction is formed. As a result, a width of the depletion region 1011 is expanded in an in-plane direction, and thus side capacitance can be reduced.

### SUMMARY OF THE INVENTION

However, in order to form the depletion regions inside the p-type semiconductor regions 2001 and in the neighboring region, concentration of impurities in the p-type semiconductor regions 2001 and widths of the p-type semiconductor regions 2001 need to be precisely controlled when positioning the p-type semiconductor regions 2001. Specifically, in order to form the depletion regions inside the highly concentrated p-type semiconductor regions 2001, widths of the p-type semiconductor regions 2001 need to be decreased (e.g. a few tenth of a micron). When each of the widths of the p-type semiconductor regions 2001 is decreased, widths of the depletion regions formed in the neighboring region of the p-type semiconductor regions 2001 are decreased as well. For this reason, in order to form the depletion region 1011 in which depletion regions unite with each other, intervals between the p-type semiconductor regions 2001 need to be shortened and the number of the p-type semiconductor regions 2001 needs to be increased.

Accordingly, a flexibility to select parameters (e.g. a width and an interval between regions) relating to the p-type semiconductor regions 2001 is limited when producing the optical semiconductor device 2000. In addition to a limitation on layout, another problem is that there is little margin in forming a few tenth of a micron wide p-type semiconductor regions 2001 and for variation in process. Therefore, it is very difficult to actually produce the optical semiconductor device 2000 that can form the depletion region 1011 in which depletion regions unite with each other in an in-plane direction by forming the p-type semiconductor regions 2001.

On the other hand, when increasing the concentration in the p-type semiconductor region 2001 or the width of the p-type semiconductor regions 2001 in order to expand a width of a depletion region formed in the neighboring region of the p-type semiconductor regions 2001, insides of the p-type semiconductor regions 2001 are not depleted. Therefore, side capacitance in a junction area of the p-type semiconductor regions 2001 and the n-type semiconductor region 1003 is newly added, and it can prevent the photodiode speed from being increased.

Also, in order to expand a width of the depletion region by positioning a plurality of the p-type semiconductor regions 2001 between the anode and the cathode electrodes, there has to be a certain distance between the anode and the cathode electrodes. This causes a size of the photodiode to be increased, and thus bottom components of junction capacitance to be increased. This can result in decrease in frequency characteristics.

Furthermore, in order to further widen the depletion region, a potential difference between each of the p-type semiconductor regions 2001 and the cathode electrode 1008 could be increased by applying a potential to each of the p-type semiconductor regions 2001. In this case, another diffused (contact) region and electrode that connect with each of the p-type semiconductor regions 2001 are required to be provided. As a result, an additional process is required and a structure becomes complex. This can lead to an increase in cost.

The above is a description about the optical semiconductor device 2000 that includes (i) the p-type semiconductor substrate 1001 as a semiconductor substrate, and (ii) the n-type semiconductor region 1003 in which a plurality of highly concentrated p-type element isolation regions 1004 are positioned. However, the same problem occurs with an optical semiconductor device that includes (i) an n-type semiconductor substrate as a semiconductor substrate, (ii) a low concentrated n-type semiconductor region that is positioned on the n-type semiconductor substrate, (iii) a p-type semiconductor region that is positioned on the n-type semiconductor region, and (iv) a plurality of highly concentrated n-type element isolation regions that are positioned in the p-type semiconductor region.

The present invention aims to provide an optical semiconductor device that reduces side capacitance without requiring an additional process.

In order to achieve the above mentioned object, Embodiment 1 of the present invention is an optical semiconductor device that performs photoelectric conversion, comprising: a semiconductor substrate that includes (i) a first conductivity-type semiconductor region, (ii) a second conductivity-type semiconductor region that is positioned on the first conductivity-type semiconductor region and has a light receiving surface, and (iii) a first conductivity-type contact region that penetrates, from an upper surface of the second conductivity-type semiconductor region, the second conductivity-type semiconductor region so as to be in contact with the first conductivity-type semiconductor region; an electrode pair for drawing current obtained by performing photoelectric conversion of light incident on the light receiving surface, the electrode pair being composed of (i) a first electrode that is positioned on the first conductivity-type contact region and (ii) a second electrode that is positioned on the second conductivity-type semiconductor region so as to be separated from the first electrode; an insulating film that is positioned on the second conductivity-type semiconductor region and in an area between the first electrode and the second electrode; and a third electrode that is positioned on the insulating film.

Here, one of the first conductivity-type and the second conductivity-type indicates n-type, and the other indicates p-type.

With the above structure, the second conductivity-type semiconductor region, the insulating film, and the third electrode form a MOS structure. Therefore, a depletion region is formed below the third electrode in the second conductivity-type semiconductor region because of a potential difference between the second electrode and the third electrode that occurs by applying, to the third electrode, voltage according to a polarity of the second conductivity-type. Since a width of a depletion region in a junction area of the second conductivity-type semiconductor region and the first conductivity-type contact region expands, side capacitance at a p-n junction of a light receiving element is reduced. Therefore, since the CR production is decreased without requiring an additional process of implanting the first conductivity-type semiconductor region into the second conductivity-type semiconductor region, a light receiving element speed can be increased.

Also, there is no need to provide a plurality of the third electrodes between the first and the second electrodes. Only one third electrode needs to be provided. Therefore, since a size of the optical semiconductor device can be reduced and a structure thereof can be simplified, a flexibility of a layout is not decreased.

Here, when the second electrode is a cathode electrode, voltage that is lower than voltage applied to the cathode electrode may be applied to the third electrode, and when the second electrode is an anode electrode, voltage that is higher than voltage applied to the anode electrode may be applied to the third electrode.

With this structure, a potential difference can be applied between the second electrode and the third electrode, at least part of the second conductivity-type semiconductor region below the third electrode can be depleted.

Here, the insulating film may be an oxide film.

In this case, the insulating film may be a LOCOS (Local Oxidation of Silicon) film or an STI (Shallow Trench Isolation).

With this structure, a thickness of the second conductivity-type semiconductor region is decreased in a junction area of the second conductivity-type semiconductor region and the first conductivity-type contact region. This causes a size of a junction area of the second conductivity-type semiconductor region and the first conductivity-type contact region to be reduced. Therefore, it becomes easier to completely deplete the second conductivity-type semiconductor region below the third electrode.

Here, the insulating film may be composed of two layers or more.

Since a width of a depletion region depends on a width and conductivity of the insulating film, the width of a depletion region can be flexibly controlled by arbitrarily selecting the width and conductivity of the insulating film.

Here, the insulating film may be a nitride film.

Since the nitride film has higher conductivity than the oxide film, a width of a depletion region can be further increased by using the nitride film as the insulating film.

Here, the first electrode and at least part of the third electrode may be integrally formed.

Since at least part of the third electrode and the first electrode are integrally formed, a depletion region can be formed in a side area without requiring an additional process. There is no need to provide an additional diffusion region and contact via. And since a structure can be simplified in this way and a distance between the first electrode and the second electrode can be decreased, a size of the light receiving element and bottom capacitance can be reduced.

Here, the third electrode may be composed of two layers or more that include a bottom electrode and a top electrode.

With this structure, a flexibility of a layout in a vicinity of the insulating film is increased. When assuming that different electron elements are integrated on the same substrate, the third electrode and the different electron elements can be produced in the same process in the optical semiconductor device.

Here, a second conductivity-type contact region may be positioned on the second conductivity-type semiconductor region so as to be in contact with the second electrode, and extend along the second conductivity-type semiconductor region to a position below the third electrode.

With this structure, even though the second conductivity-type semiconductor region is below the contact region, a depletion region can be formed below the third electrode in the second conductivity-type semiconductor region. Therefore, it becomes possible to decrease a dead space and effectively widen a depletion region. And, an interval between the first electrode and the second electrode can be reduced.

Here, the optical semiconductor device may further comprise: a division unit configured to divide the light receiving surface into a plurality of areas; and a fourth electrode that is positioned on the division unit.

With this structure, since at least part of the second conductivity-type semiconductor region in the vicinity of the division unit can be depleted, a depletion region in the vicinity of the division unit can be widened, and side capacitance can be reduced.

Here, the third electrode and the fourth electrode may be electrically connected with each other.

With this structure, a structure of the optical semiconductor device can be simplified.

Here, a width of the fourth electrode may be greater than a width of the division unit, and the fourth electrode may be made of a material that transmits light and has conductivity.

With this structure, since light transmission can be improved in the second conductivity-type semiconductor region in a vicinity of the division unit, carriers generated in the second conductivity-type semiconductor region are increased, and photosensitivity are increased. In addition to this effect, it becomes possible to further widen a depletion region, and side capacitance can be further reduced.

Here, the optical semiconductor device may further comprise one or more electron elements positioned on the semiconductor substrate.

With this structure, these elements can be mounted on one chip, and downsized, and the number of a package and a bonding wire can be reduced. Therefore, parasitic capacitance and parasitic inductance can be reduced and a photodiode speed can be increased.

### BRIEF DESCRIPTION OF THE DRAWINGS

These and the other objects, advantages and features of the invention will become apparent from the following description thereof taken in conjunction with the accompanying drawings which illustrate a specific embodiment of the invention.

In the drawings:

FIG. 1 is a cross-sectional view showing a structure of an optical semiconductor device 100 in Embodiment 1;

FIG. 2 is a top view of the optical semiconductor device 100;

FIG. 3 shows a production process of the semiconductor device 100;

FIG. 4 is a cross-sectional view showing a structure of an optical semiconductor device 200 in Embodiment 2;

FIG. 5A is a correlation diagram showing a relationship between a width of a depletion region and a thickness of a plate oxide film, and FIG. 5B is a correlation diagram showing a relationship between the width of a depletion region and a potential difference between a cathode electrode and a plate electrode;

FIG. 6 is a cross-sectional view showing a structure of an optical semiconductor device 200a in modification of Embodiment 2;

FIG. 7 is a cross-sectional view showing a structure of an optical semiconductor device 300 in Embodiment 3;

FIG. 8 is a cross-sectional view showing a structure of an optical semiconductor device 400 in Embodiment 4;

FIGS. 9A and 9B are top views of the optical semiconductor device 400;

FIG. 10 is a cross-sectional view showing a structure of an optical semiconductor device 400a in modification of Embodiment 4;

FIG. 11 is a cross-sectional view showing a structure of an optical semiconductor device 1000; and

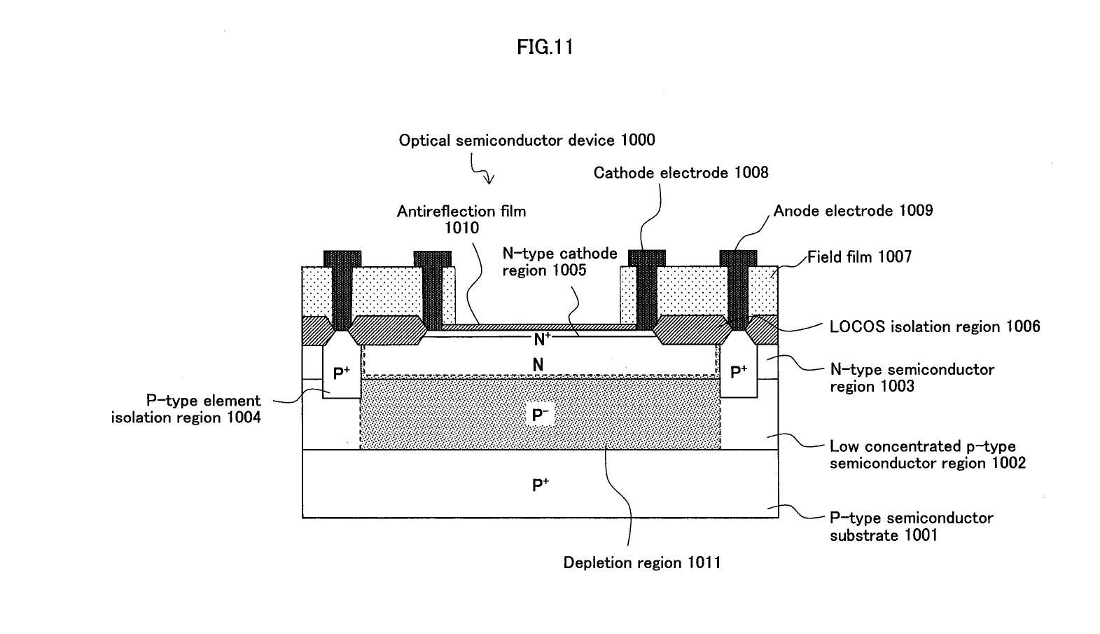

FIG. 12 is a cross-sectional view showing a structure of an optical semiconductor device 2000.

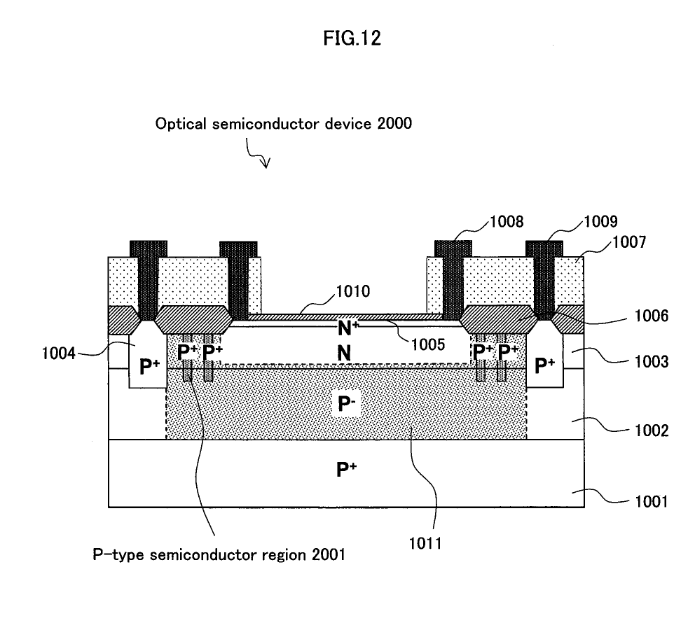

### DESCRIPTION OF THE PREFERRED EMBODIMENTS

The following describes an optical semiconductor device pertaining to the present invention with reference to the drawings.

### 1. Embodiment 1

### 1-1. Structure of Optical Semiconductor Device

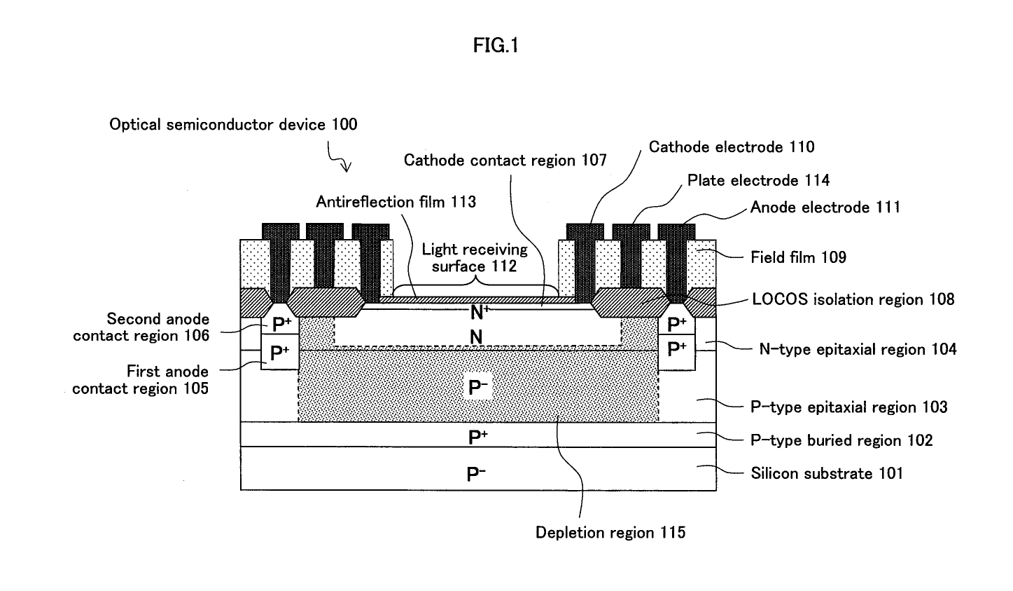

FIG. 1 is a cross-sectional view showing a structure of an optical semiconductor device 100. By way of example, in FIG. 1, a low concentrated p-type silicon substrate 101 is illustrated as a semiconductor substrate, and a PIN photodiode is illustrated as a light receiving element.

As shown in FIG. 1, the optical semiconductor device 100 includes a low concentrated p-type silicon substrate 101, a highly concentrated p-type buried region 102, a low concentrated p-type epitaxial region 103, an n-type epitaxial region 104, a highly concentrated p-type first anode contact region (an anode buried region) 105, a highly concentrated p-type second anode contact region 106, a highly concentrated n-type cathode contact region 107, a LOCOS isolation region 108, a field film 109, a cathode electrode 110, an anode electrode 111, an antireflection film 113 (e.g. an oxide film and a nitride film), and a plate electrode 114. The p-type buried region 102 is positioned on the p-type silicon substrate 101. The p-type epitaxial region 103 is positioned on the p-type buried region 102. The n-type epitaxial region 104 is positioned on the p-type epitaxial region 103. The p-type first anode contact region 105 is selectively positioned in a vicinity of an interface between the p-type epitaxial region 103 and the n-type epitaxial region 104. The p-type second anode contact region 106 is positioned on the first anode contact region 105. The n-type cathode contact region 107 is selectively positioned on the n-type epitaxial region 104. The LOCOS isolation region 108 is selectively positioned on the n-type epitaxial region 104. The field film 109 is positioned on the n-type epitaxial region 104 and the LOCOS isolation region 108. The cathode electrode 110 is selectively positioned on the cathode contact region 107. The anode electrode 111 is positioned on the second anode contact region 106. The antireflection film 113 is positioned on a light receiving surface 112 that is formed by opening the field film 109. And the plate electrode 114 is positioned on the LOCOS isolation region 108 between the cathode electrode 110 and the anode electrode 111. A light receiving surface of a photodiode has, for example, a square or rectangular shape 10 μm to a few mm on a side, or a circular shape with a diameter of approximately 10 μm to a few mm.

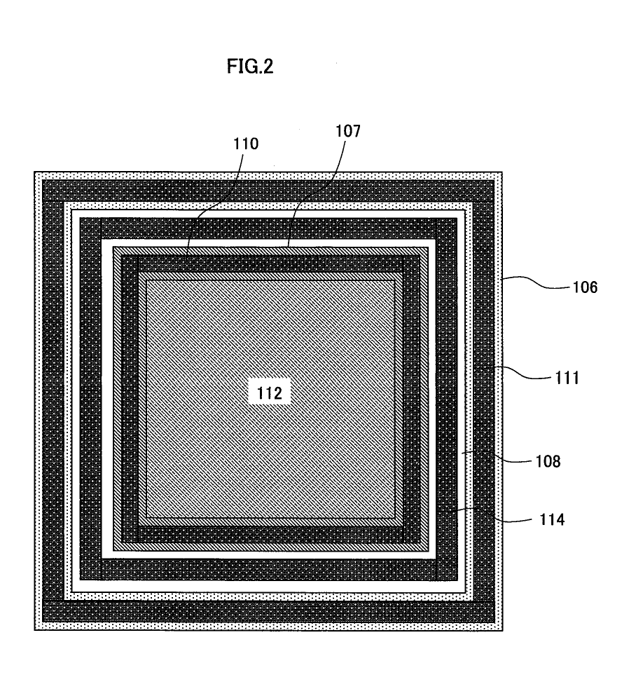

The following describes a positional relationship among the plate electrode 114, the cathode electrode 110 and the anode electrode 111 in more detail. FIG. 2 is a top view of the optical semiconductor device 100. As shown in FIG. 2, the cathode electrode 110 is positioned on the cathode contact region 107 around a perimeter of the light receiving surface 112 so as to surround the light receiving surface 112. The plate electrode 114 is positioned on the LOCOS isolation region 108 between the second anode contact region 106 and the cathode contact region 107 so as to surround the cathode electrode 110. Also, the anode electrode 111 is positioned on the second anode contact region 106 that is positioned around a cathode so as to surround the plate electrode 114.

In the optical semiconductor device 100 having the above structure, light incident on the light receiving surface 112 having been provided with the antireflection film 113 is absorbed by the n-type epitaxial region 104 as a cathode and the p-type epitaxial region 103 as an anode. Consequently, electron-hole pairs are generated. When a reverse bias is applied between the cathode electrode 110 and the anode electrode 111 at this time, a depletion region 115 is formed such that it expands toward the p-type epitaxial region 103. This is because the p-type epitaxial region 103 has lower concentration of impurities.

In a junction area of (i) the first anode contact region 105 and the second anode contact region 106 and (ii) the n-type epitaxial region 104, the n-type epitaxial region 104, the LOCOS isolation region 108 and the plate electrode 114 form a MOS (Pch) structure. Therefore, when voltage that is lower than that applied to the cathode electrode 110 is applied to the plate electrode 114, the depletion region 115 is formed such that it expands toward the n-type epitaxial region 104. By increasing a potential difference between the cathode electrode 110 and the plate electrode 114, an edge of the depletion region 115 can reach an interface between the p-type epitaxial region 103 and the n-type epitaxial region 104.

The electrons of the electron-hole pairs generated in a vicinity of the depletion region 115 are transferred to the cathode contact region 107 and the holes are transferred to the first anode contact region 105 by diffusion and drift. Then the electrons are drawn from the cathode electrode 110, and the holes are drawn from the anode electrode 111 both as photocurrent.

In addition to decreasing concentration of impurities in the p-type epitaxial region 103 to completely deplete the p-type epitaxial region 103, an area below the plate electrode 114 is also depleted. This causes a drift current, which is a high speed component, to be dominant as photocurrent. And since a diffusion current, which is a low speed component, hardly contributes to the photocurrent, a photodiode speed can be increased. Also, due to an increase of a depletion region in a junction area of (i) the n-type epitaxial region 104 and (ii) the first anode contact region 105 and the second anode contact region 106, parasitic capacitance is reduced. This leads to a decrease of the CR production, and the photodiode speed can be increased.

Since a part of the LOCOS isolation region 108 is positioned on an upper surface of the n-type epitaxial region 104, a thickness of the n-type epitaxial region 104 below the plate electrode 114 is effectively decreased. This makes the n-type epitaxial region 104 below the plate electrode 114 to be easily depleted.

Also, since the p-type buried region 102 has higher concentration of impurities than the silicon substrate 101, a potential barrier is formed in a vicinity of an interface between the p-type buried region 102 and the silicon substrate 101. As the silicon substrate 101 is not depleted, carriers generated in the silicon substrate 101 are transferred by diffusion. However, these carriers are blocked by the potential barrier and cannot reach the p-type epitaxial region 103. These carriers are recombined in the p-type buried region 102. As seen from the above, a diffusion current arising from carriers generated in the silicon substrate 101 does not contribute to a photocurrent. Accordingly, since diffusion current components are further reduced in the photocurrent, the photodiode speed can be further increased.

Furthermore, since the cathode contact region 107 is positioned on the n-type epitaxial region 104 and the cathode electrode 110 is in contact with the cathode contact region 107, cathode resistance can be reduced. This reduces parasitic resistance, and thus the photodiode speed can be further increased.

### 1-2. Method for Producing Optical Semiconductor Device

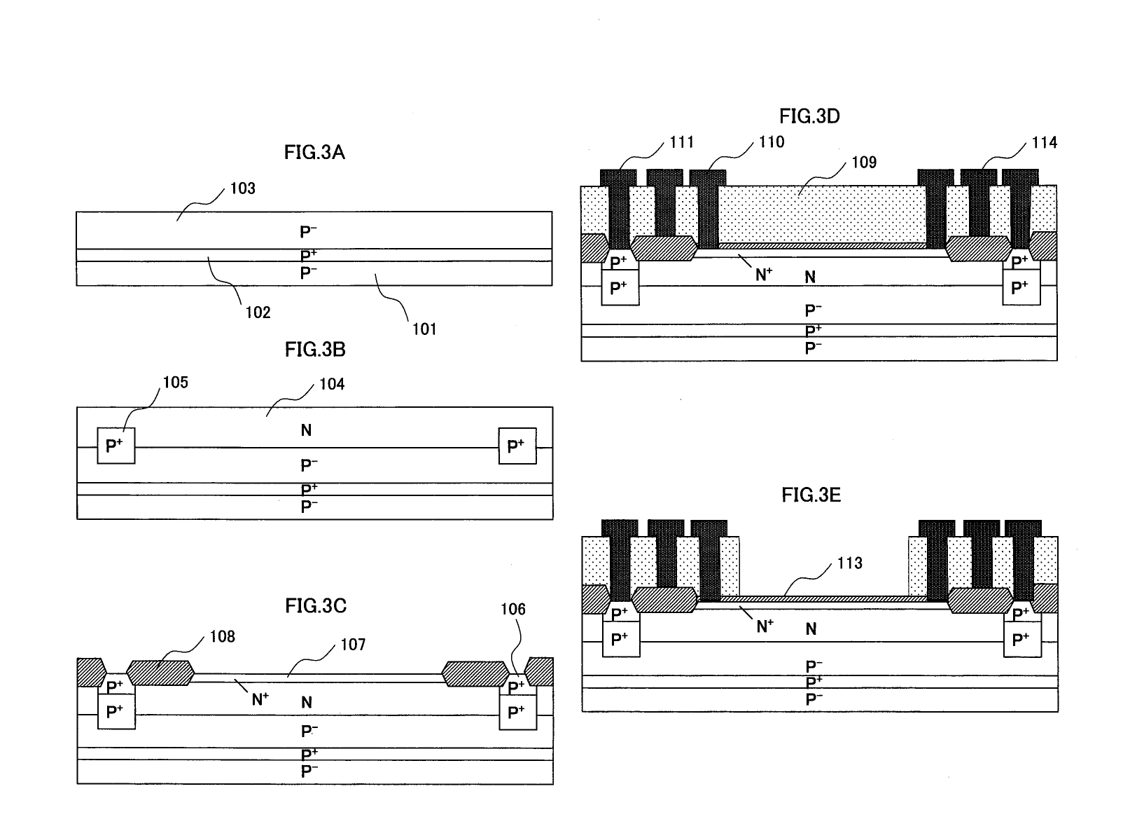

The following describes a method for producing an optical semiconductor device. FIGS. 3A to 3D illustrate cross-sectional views each showing a structure of the optical semiconductor device 100 in each production process.

First, in the silicon substrate 101, the p-type buried region 102 is formed by ion implantation and so on. Then, the p-type epitaxial region 103 (e.g. 10 μm thick and 1×10¹⁴ cm⁻³ concentration) is formed (FIG. 3A).

Next, after the first anode contact region 105 is selectively formed in the p-type epitaxial region 103 by ion implantation and so on, the n-type epitaxial region 104 (e.g. 1.0 μm thick and 1×10¹⁶ cm⁻³ concentration) is formed on the p-type epitaxial region 103 (FIG. 3B).

Then, the second anode contact region 106 is formed on the first anode contact region 105, the cathode contact region 107 is formed on the n-type epitaxial region 104, and the LOCOS isolation region 108 (e.g. 400 nm thick) is formed in a boundary area between the second anode contact region 106 and the cathode contact region 107, and an element isolation area (FIG. 3C).

Furthermore, after the field film 109 is formed over the entire surfaces of the n-type epitaxial region 104 and the LOCOS isolation region 108 by a CVD method and so on, the cathode electrode 110, the anode electrode 111, and the plate electrode 114 (e.g. 1.0 μm thick and made of Ti/TiN/Al) are selectively formed, by a sputtering method and so on, in contact holes that have been formed by selectively opening the field film 109 (FIG. 3D).

Finally, after forming a protective film (not illustrated) on the top surface, the light receiving surface 112 is formed by opening the protective film and the field film 109 to expose the antireflection film 113, and a photodiode is formed (FIG. 3E).

AS described above, the plate electrode 114 is formed between the cathode electrode 110 and the anode electrode 111 in this embodiment. By applying a potential difference between the cathode electrode 110 and the plate electrode 114, a depletion region can be formed in a junction area of (i) the first anode contact region 105 and the second anode contact region 106 and (ii) the n-type epitaxial region 104. And, by increasing the potential difference, a width of the depletion region formed in the junction area expands. This can drastically reduce side components of junction capacitance. As a result, the CR production is decreased, and the photodiode speed can be increased.

What is more, since only one plate electrode 114 needs to be positioned between the cathode electrode 110 and the anode electrode 111, a depletion region can be formed with a simple structure without complicating a layout.

Incidentally, a penetration depth of light into silicon varies depending on a wavelength of incident light, because the absorption coefficient of silicon varies depending on the wavelength of incident light.

However, an optimal structure for the wavelength can be determined by appropriately choosing a thickness of the p-type epitaxial region 103 and concentration of impurities in the p-type epitaxial region 103. Accordingly, without relying on structures around the plate electrode, the photodiode speed can be increased by completely depleting the p-type epitaxial region 103, reducing a diffusion current that contributes as photocurrent and causing a drift current to be dominant. That is to say, the present invention is applicable in any wavelength region in which a silicon has sensitivity, and side capacitance is expected to be reduced.

### 2. Embodiment 2

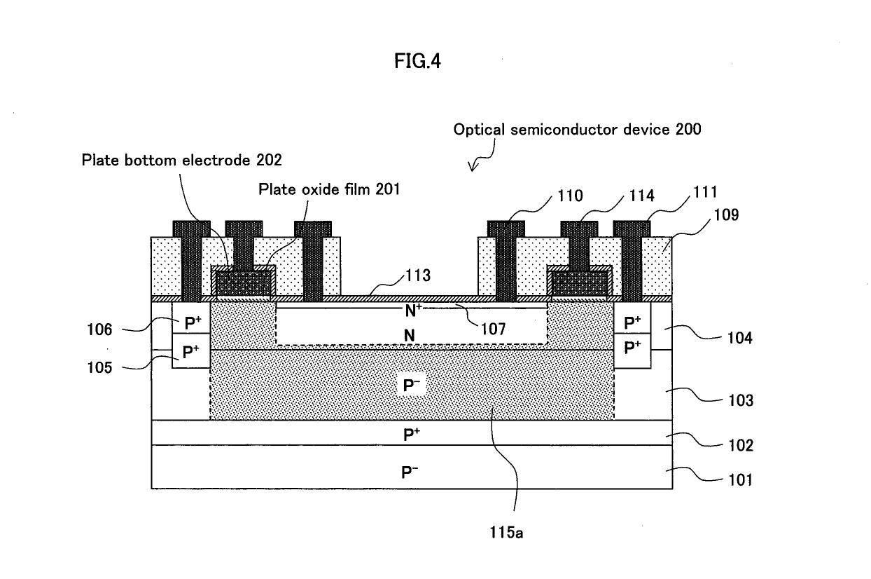

FIG. 4 is a cross-sectional view showing a structure of an optical semiconductor device 200. As shown in FIG. 4, the optical semiconductor device 200 includes a plate oxide film 201 and a plate bottom electrode 202. The plate oxide film 201 is positioned on the n-type epitaxial region 104 and in a boundary area between the second anode contact region 106 and the cathode contact region 107. The plate bottom electrode 202 is positioned on the plate oxide film 201. The plate electrode 114 is positioned on the plate bottom electrode 202. The plate bottom electrode 202 is made, for example, of polysilicon and amorphous silicon. The other structures are the same as those in FIG. 1.

As seen from the above, the optical semiconductor device 200 has a structure in which the plate oxide film 201 is used in place of the LOCOS isolation region 108 in the optical semiconductor device 100 in Embodiment 1, and the plate bottom electrode 202 is positioned on the plate oxide film 201. The plate oxide film 201 can be made thinner than the LOCOS isolation region 108.

Also, the plate bottom electrode 202 is for positioning an electrode on the thin plate oxide film 201. Here, in, for example, an OEIC that is produced by integrating MOS transistors on the same substrate, the plate oxide film 201 can be used as a gate oxide film in the MOS transistor, and the plate bottom electrode 202 can be used as a gate polysilicon electrode.

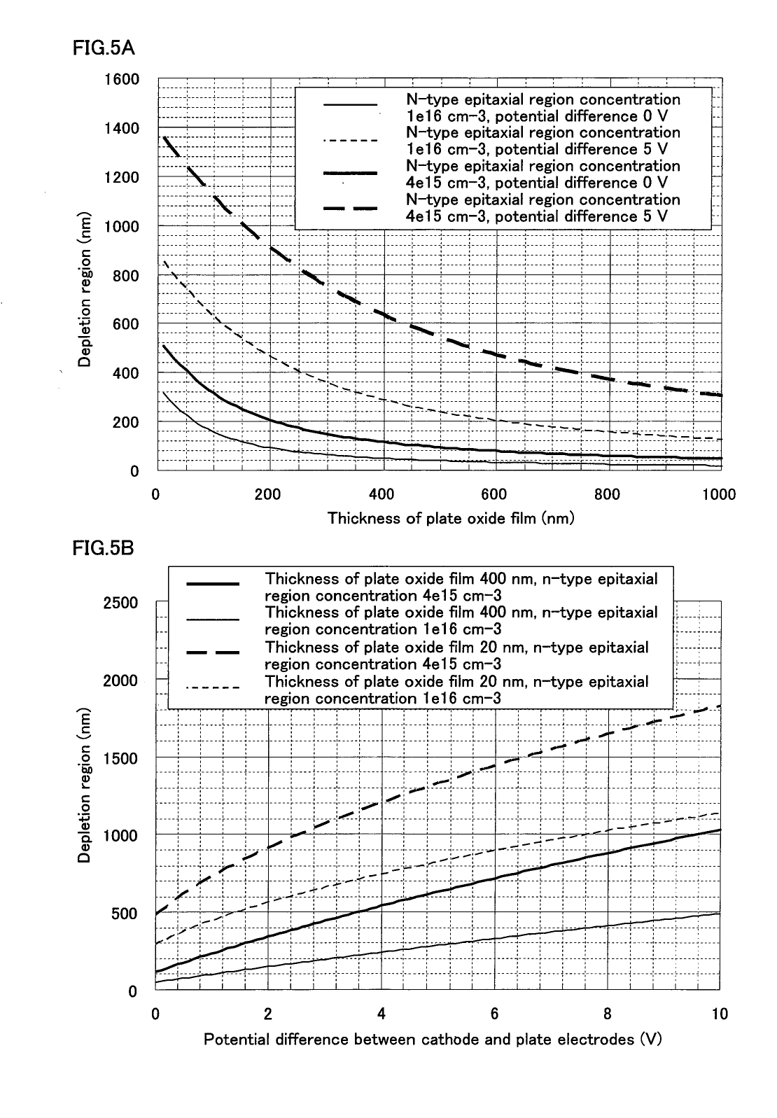

The following describes (i) a relationship between a width of a depletion region and a thickness of the plate oxide film and (ii) a relationship between the width of a depletion region and a potential difference applied between the cathode electrode 110 and the plate electrode 114. FIG. 5A shows the relationship between the width of a depletion region and the thickness of the plate oxide film. FIG. 5A shows the relationship when changing concentration of impurities in the n-type epitaxial region 104 and the potential difference applied between the cathode electrode 110 and the plate electrode 114. FIG. 5B shows the relationship between the width of a depletion region and the potential difference applied between the cathode electrode 110 and the plate electrode 114. FIG. 5B shows the relationship when changing concentration of impurities in the n-type epitaxial region 104 and the thickness of the plate oxide film.

As shown in FIG. 5A, the thinner the plate oxide film is, the more the depletion region expands. The depletion region expands more when a potential difference is 5 V than when the potential difference is 0 V under the same condition for concentration of impurities in the n-type epitaxial region 104 and a thickness of the plate oxide film. And the depletion region expands more when concentration of impurities in the n-type epitaxial region 104 is lower under the same condition for a potential difference and the thickness of the plate oxide film.

As shown in FIG. 5B, the larger the potential difference between the cathode electrode 110 and the plate electrode 114 is, the more the depletion region expands. The following describes an example when concentration of impurities in the n-type epitaxial region 104 is 4×10¹⁵ cm⁻³, and a thickness of the n-type epitaxial region 104 is 1.0 μm. In order to completely deplete an entire boundary area between the anode and the cathode in the n-type epitaxial region 104, 9.5 V or more potential difference is required when the thickness of the plate oxide film is 400 nm. On the other hand, the entire boundary area is completely depleted by applying a potential difference of about 2.5 V, when the thickness of the plate oxide film is 20 nm. In the latter case, side capacitance can be reduced by applying lower voltage. Therefore, it is applicable to various circuits because a depletion region can expand in a low voltage circuit.

The following describes another example when concentration of impurities in the n-type epitaxial region 104 is 1×10¹⁶ cm⁻³, and a thickness of the n-type epitaxial region 104 is 1.0 μm. When the thickness of the plate oxide film is 20 nm, the entire boundary area is completely depleted by applying a potential difference of about 7.7 V. That is to say, when the n-type epitaxial region 104 has relatively high concentration, the entire boundary area can be completely depleted by increasing a potential difference. Therefore, side capacitance can be reduced.

It is assumed here that a width of the plate electrode 114 is 5 μm, and a potential difference between the cathode electrode 110 and the anode electrode 111 is 5.0 V. In a 50 μm square photodiode, when the plate electrode 114 is not included, bottom capacitance and side capacitance are 30 fF and 15 fF, respectively (45 fF in total).

On the other hand, when the plate electrode 114 is included, side capacitance is reduced to 4.2 fF, and junction capacitance becomes 34.2 fF in total, decreasing by about 24%.

In a 100 μm×20 μm rectangular photodiode, which is largely affected by its perimeter, bottom capacitance and, side capacitance are 24 fF and 18.2 fF, respectively (42.2 fF in total) when the plate electrode 114 is not included.

On the other hand, when the plate electrode 114 is included, side capacitance is reduced to 2.9 fF, and junction capacitance becomes 26.9 fF in total, considerably decreasing by about 36%.

Accordingly, in this embodiment, the n-type epitaxial region 104 can completely and easily be depleted. It is realized by (i) reducing the thickness of the plate oxide film, even when a potential difference between the cathode electrode 110 and the plate electrode 114 is small, and by (ii) increasing a potential difference between the cathode electrode 110 and the plate electrode 114, even when the n-type epitaxial region 104 has relatively high concentration. Since side components of junction capacitance can be reduced by completely depleting the n-type epitaxial region 104, the photodiode speed can be increased.

### Modification

The following describes a modification in which the cathode contact region 107 and the plate oxide film 201 are positioned so as to partially contact with each other.

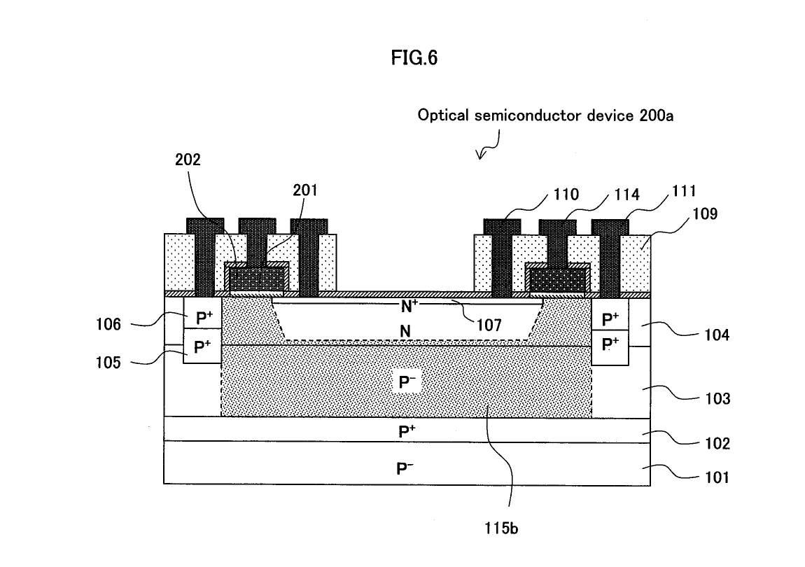

FIG. 6 is a cross-sectional view showing a structure of an optical semiconductor device 200a. As shown in FIG. 6, the optical semiconductor device 200a has a structure in which the plate oxide film 201 is extended to an upper area of the cathode contact region 107. With this structure, it is possible to decrease a dead space and effectively widen a depletion region to both edges of the cathode contact region 107. As a result, an interval between the cathode electrode 100 and the anode electrode 111 can be minimized.

### 3. Embodiment 3

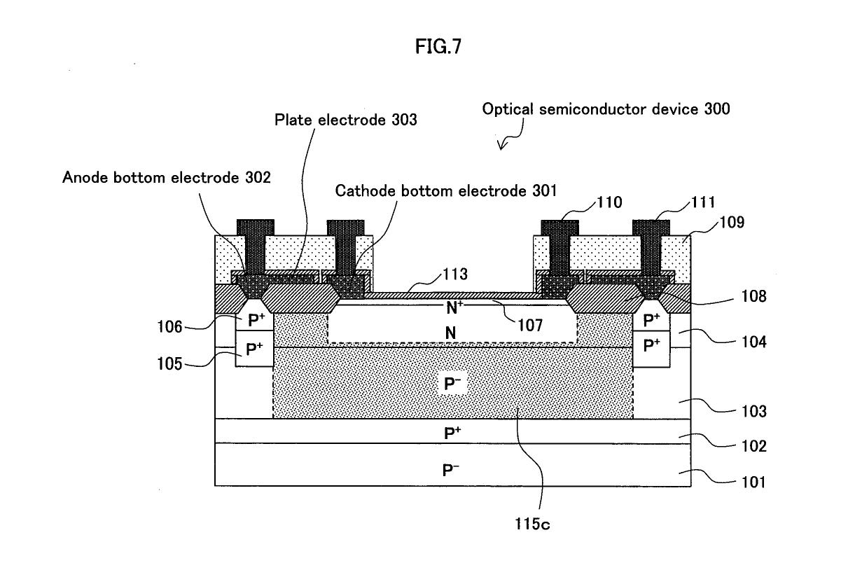

FIG. 7 is a cross-sectional view showing a structure of an optical semiconductor device 300. As shown in FIG. 7, the optical semiconductor device 300 includes a cathode bottom electrode 301, an anode bottom electrode 302 and a plate electrode 303. The cathode bottom electrode 301 is selectively positioned on the cathode contact region 107. The anode bottom electrode 302 is positioned on the second anode contact region 106. The plate electrode 303 is positioned on the LOCOS isolation region 108 so as to be integrated with the anode bottom electrode 302. The cathode electrode 110 is positioned on the cathode bottom electrode 301, and the anode electrode 111 is positioned on the anode bottom electrode 302. The other structures are the same as those in FIG. 1.

In order to widen a depletion region in a junction area of (i) the first anode contact region 105 and the second anode contact region 106 and (ii) the n-type epitaxial region 104, there needs to be a potential difference between the plate electrode 303 and the cathode electrode 110 (+ to the cathode electrode 110).

Since the optical semiconductor device 300 has a structure in which the anode bottom electrode 302 and the plate electrode 303 are integrated, a depletion region at the side can be expanded by applying a reverse bias between the cathode electrode 100 and the anode electrode 111.

Also, since reverse voltage is generally applied to a photodiode, the cathode bottom electrode 301 and the plate electrode 303 can be formed so as to be integrated with each other depending on a use condition and a structure.

As described above, in this embodiment, the plate electrode 303 can be formed so as to be integrated with the cathode bottom electrode or the anode bottom electrode. As a result, the structure of the optical semiconductor device 300 can be simplified without requiring an additional process.

Also, with the above structure of the plate electrode, there is no need to separately provide the plate electrode as shown in Embodiment 1. This causes a flexibility of a layout to be increased, and a distance between the cathode electrode and the anode electrode can be reduced. As a result, a junction area of the p-type epitaxial region 103 and the n-type epitaxial region 104 is reduced, and parasitic capacitance at the junction area is reduced.

### 4. Embodiment 4

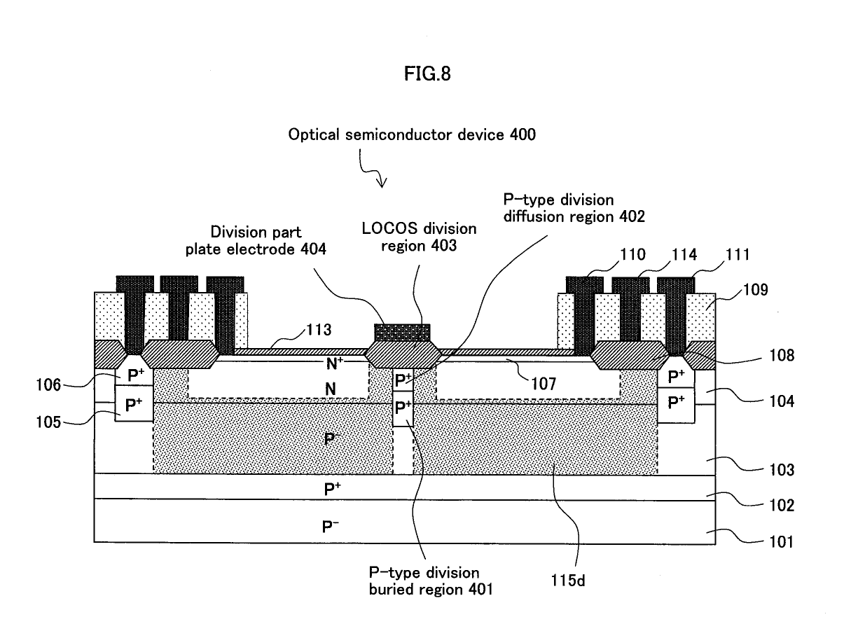

FIG. 8 is a cross-sectional view showing a structure of an optical semiconductor device 400. The optical semiconductor device 400 includes a highly concentrated p-type division buried region 401, a highly concentrated p-type division diffusion region 402, a LOCOS division region 403 and a division part plate electrode 404. The p-type division buried region 401 is selectively positioned in a vicinity of an interface between the p-type epitaxial region 103 and the n-type epitaxial region 104. The division diffusion region 402 is selectively positioned on the division buried region 401 and in the n-type epitaxial region 104. The LOCOS division region 403 is positioned on the division diffusion region 402. The division part plate electrode 404 is selectively positioned on the LOCOS division region 403. The p-type division buried region 401 may be formed in the same process as the first anode contact region 105, the p-type division diffusion region 402 may be formed in the same process as the second anode contact region 106, and the LOCOS division region 403 may be formed in the same process as the LOCOS isolation region 108, respectively. The other structures are the same as those in Embodiment 1.

As seen from the above, the optical semiconductor device 400 has a structure in which the n-type epitaxial region 104 in the optical semiconductor device 100 described in Embodiment 1 is divided into a plurality of areas with the p-type division buried region 401, the p-type division diffusion region 402 and the LOCOS division region 403. Each of the divided area functions as a photodiode. These photodiodes are electrically independent with each other by being divided with the p-type division buried region 401, the p-type division diffusion region 402 and the LOCOS division region 403.

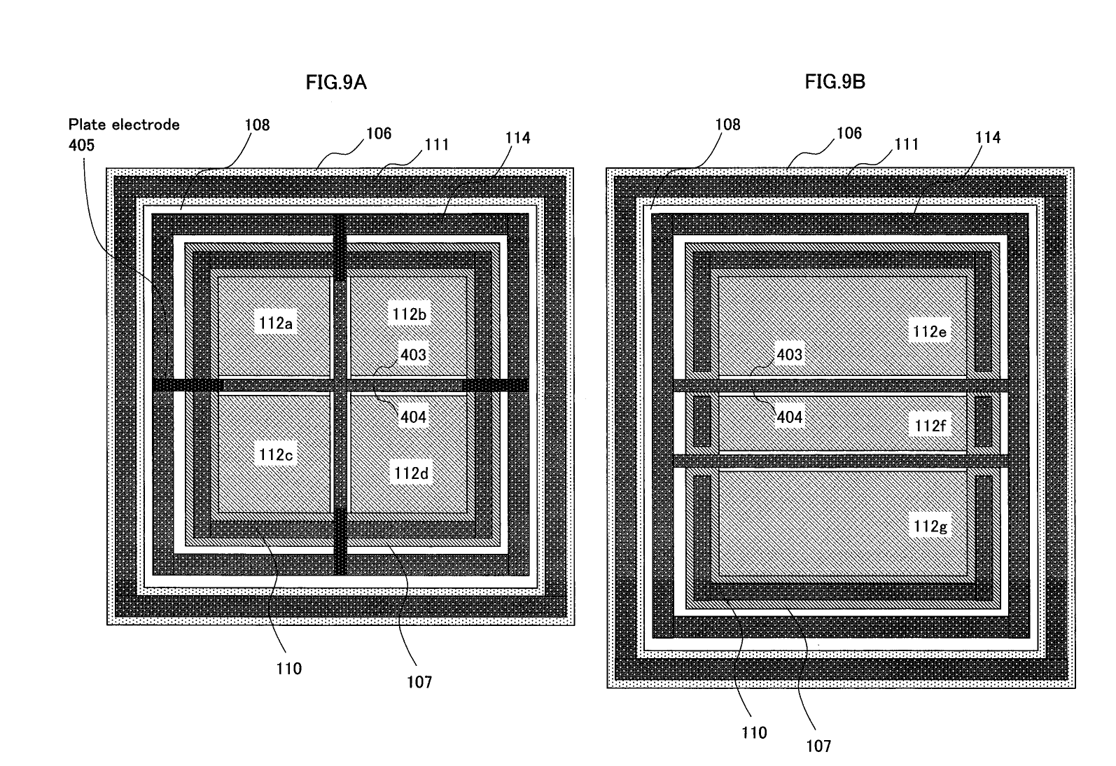

The following describes how the light receiving surface 112 is divided with the p-type division buried region 401, the p-type division diffusion region 402 and the LOCOS division region 403 in detail. FIGS. 9A and 9B show top views of the optical semiconductor device 400. FIG. 9A shows a structure in which the light receiving surface 112 is cross-divided into four areas, whereas FIG. 9B shows a structure in which the light receiving surface 112 is transversely divided into three rectangles.

In FIG. 9A, the light receiving surface 112 is divided into four areas, namely, light receiving surfaces 112a, 112b, 112c and 112d, with the p-type division buried region 401, the p-type division diffusion region 402 and the LOCOS division region 403. A cathode electrode is positioned in each divided area. Therefore, each of the divided areas functions as an independent photodiode. The division part plate electrode 404 positioned on the LOCOS division region 403 is connected to the plate electrode 114 via a sterically-positioned plate electrode 405 without being electrically connected to the cathode electrode 110. Voltage that is lower than that applied to the cathode electrode 110 is applied to the division part plate electrode 404.

In FIG. 9B, the light receiving surface 112 is divided into three areas, namely, light receiving surfaces 112e, 112f and 112g, with the p-type division buried region 401, the p-type division diffusion region 402 and the LOCOS division region 403. A cathode electrode is positioned in each divided area similarly to FIG. 9A. As shown in FIG. 9B, each cathode electrode positioned in each of the divided area is independent without being in contact with the other cathode electrodes positioned in the other divided areas. The division part plate electrode 404 is positioned so as to be connected to the plate electrode 114 through a gap between cathode electrodes. Voltage that is lower than that applied to the cathode electrode 110 is applied to the division part plate electrode 404.

With this structure, a p-n junction is formed at a junction of (i) the n-type epitaxial region 104 and (ii) the highly concentrated p-type division buried region 401 and the highly concentrated p-type division diffusion region 402 (hereinafter, also referred to as a “division part”). Therefore, side capacitance at the p-n junction is added. Here, voltage that is lower than that applied to the cathode electrode 110 is applied to the division part plate electrode 404, and a potential difference occurs between the division part plate electrode 404 and the cathode electrode 110. This can cause a depletion region to expand toward the n-type epitaxial region 104 and reduce side capacitance in the division part as with an effect produced by the above-mentioned plate electrode 114.

As described above, in this embodiment, in addition to a junction area of (i) the first anode contact region 105 and the second anode contact region 106 and (ii) the n-type epitaxial region 104, a depletion region formed in the division part can be expanded. As a result, side capacitance in the division part can be reduced.

### Modification

The following describes a modification in which the division part plate electrode 404 is replaced by a transparent division part plate electrode 406.

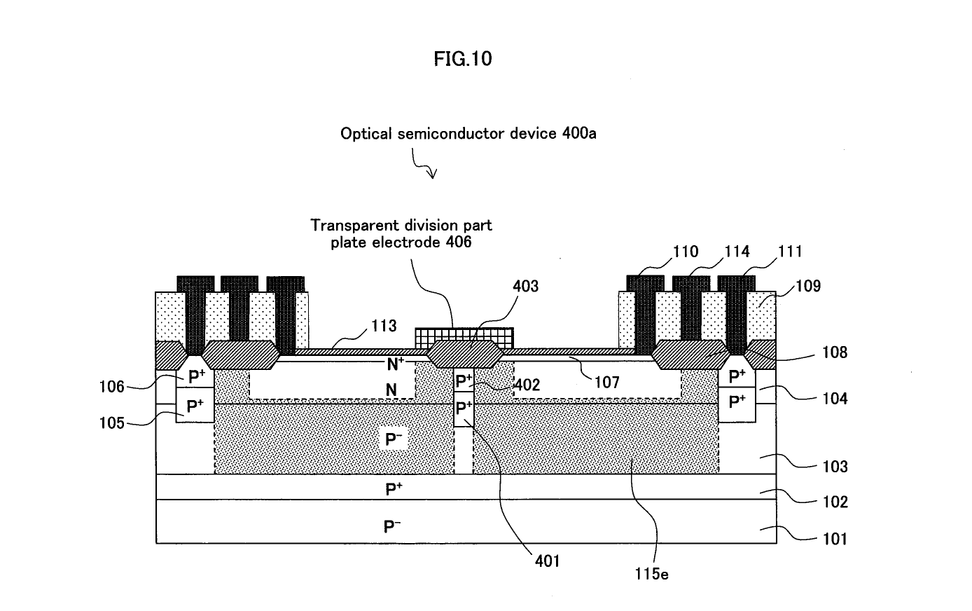

FIG. 10 is a cross-sectional view showing a structure of an optical semiconductor device 400a. In place of the division part plate electrode 404 in the optical semiconductor device 400, the optical semiconductor device 400a includes the transparent division part plate electrode 406 positioned on the LOCOS division region 403. The other structures of the optical semiconductor device 400a are the same as those of the optical semiconductor device 400.

An electrode that transmits light is used as the transparent division part plate electrode 406. The transparent division part plate electrode 406 is made, for example, of ITO (Indium Tin Oxide) and tin oxide. With this structure, as shown in FIG. 10, the transparent division part plate electrode 406 is expanded to outside the LOCOS division region 403. As a result, a depletion region in the division part can be more widen, and side capacitance can be further reduced.

Even if the transparent division part plate electrode 406 overlaps the light receiving surface 112, the light receiving surface can be effectively used, because the transparent division part plate electrode 406 transmits light and the light is absorbed in an area below the transparent division part plate electrode 406.

### Others

The present invention has been explained in accordance with the above embodiments, however it is obvious that the present invention is not limited to the above embodiments.

(1) In the above embodiments, although the silicon substrate 101 is used as a semiconductor substrate, it is not limited to be the silicon substrate. For example, a germanium substrate that is widely used in a long wavelength region and a compound semiconductor may be used as the semiconductor substrate.

(2) In the above embodiments, an anode part has a three-region structure composed of the silicon substrate 101, the p-type buried region 102 and p-type epitaxial region 103. However, it may have a structure only composed of the low concentrated p-type silicon substrate 101, or a two-region structure composed of the highly concentrated p-type silicon region 101 and the p-type epitaxial region 103.

That is to say, a first conductivity-type semiconductor region may have (i) the three-region structure composed of the silicon substrate 101, the p-type buried region 102 and p-type epitaxial region 103 as well as (ii) the two-region structure composed of the highly concentrated p-type silicon substrate 101 and the p-type epitaxial region 103 or (iii) the structure only composed of the low concentrated p-type silicon substrate 101.

(3) In the above embodiments, although an electrode is made of Ti/TiN/Al, it may be made of another kind of metal and barrier metal, a compound and a silicide including these metals, or material that has a layered structure of these.

(4) In the above embodiments, although a PIN photodiode is used as the light receiving element, it is obvious that an avalanche photodiode and a phototransistor may also be used as the light receiving element.

(5) In the above embodiments, a p-type semiconductor region is used as the first conductivity-type semiconductor region, and an n-type semiconductor region is used as the second conductivity-type semiconductor region. However, it is obvious that the n-type semiconductor region may be used as the first conductivity-type semiconductor region, and the p-type semiconductor region may be used as the second conductivity-type semiconductor region.

(6) In the above embodiments, an optical semiconductor device including a photodiode is described. However, it is obvious that an OEIC that is produced by integrating electronic elements such as a bipolar transistor, a MOS transistor, a resistive element, a capacitance element and the like on the same substrate may be applied.

Here, when the technology disclosed in Japanese Patent Application Publication No. 2008-117952 is applied to an OEIC that is produced by integrating NPN transistors on the same substrate, the n-type semiconductor region 1003 is often used as a collector. In this case, in order to increase a NPN transistor speed, collector resistance needs to be reduced. Therefore, the n-type semiconductor region 1003 needs to be highly concentrated.

On the other hand, a width of a depletion region formed in the one p-type element isolation region 1004 depends on concentration of impurities in the n-type semiconductor region 1003. For this reason, in order to increase the width of the depletion region, the n-type semiconductor region 1003 needs to be low concentrated. That is to say, there is a trade-off therebetween. Accordingly, in order to widen the depletion region, intervals at which the p-type semiconductor regions 2001 are implanted need to be reduced and the number of the p-type semiconductor regions 2001 needs to be increased. Therefore, limitations on the layout are placed.

By forming the plate electrode 114 between the cathode electrode 110 and the anode electrode 111, and by applying a potential difference between the cathode electrode 110 and the plate electrode 114, a depletion region can be formed in a junction area of (i) the first anode contact region 105 and the second anode contact region 106 and (ii) the n-type epitaxial region 104 without placing the limitations on the layout. Also, when the n-type semiconductor region 1003 has relatively high concentration, a depletion region can be formed.

(7) In the above embodiments, the optical semiconductor device has a two-region structure composed of the first anode contact region 105 and the second anode contact region 106. However, the optical semiconductor device may include only one of the two regions. Alternatively, the optical semiconductor device does not necessarily need to include the n-type cathode contact region 107 for operation of a photodiode, because the n-type cathode contact region 107 is formed to decrease resistance.

(8) In the above embodiments 1 and 4, although a LOCOS film is used as an insulating film, an STI (Shallow Trench Isolation) may be used as the insulating film. This allows a width of the insulating film to be reduced. Therefore, a size of a photodiode and bottom capacitance can be reduced.

(9) In the above embodiment 2, although the plate oxide film 201 is used as an insulator, a nitride film that has higher conductivity and the like may be used instead of the plate oxide film 201. In this case, since the nitride film has higher conductivity than the oxide film, a depletion region can be further expanded even if a thickness of the nitride film is the same as a thickness of the oxide film. Also, a laminated film composed, for example, of (i) the oxide film and the nitride film or (ii) a LOCOS film and a field film may be used instead of the plate oxide film 201. In this case, since the plate electrode 114 may, for example, be positioned immediately on the laminated film without opening the field film 109, a structure can be simplified.

(10) In the above embodiment 4, the optical semiconductor device 400 has a structure in which the n-type epitaxial region 104 is divided into a plurality of areas with the p-type division buried region 401, the p-type division diffusion region 402 and the LOCOS division region 403. However, the n-type epitaxial region 104 may be divided with the p-type division buried region 401 and the p-type division diffusion region 402, or may be divided only with the LOCOS division region 403.

(11) In the above embodiments, although the plate electrode has a rectangular shape as shown in FIG. 2, the shape is not limited to this. It may have a ring shape and other shapes.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

### INDUSTRIAL APPLICABILITY

The present invention can be broadly applied to an optical semiconductor device that includes a light receiving element, and it is especially useful in an OEIC.

### REFERENCE SIGNS LIST

100 optical semiconductor device
101 silicon substrate
102 p-type buried region
103 p-type epitaxial region
104 n-type epitaxial region
105 first anode contact region
106 second anode contact region
107 cathode contact region
108 LOCOS isolation region
109 field film
110 cathode electrode
111 anode electrode
112 light receiving surface
113 antireflection film
114 plate electrode
201 plate oxide film
202 plate bottom electrode
301 cathode bottom electrode
302 anode bottom electrode
401 p-type division buried region
402 p-type division diffusion region
403 LOCOS division region
404 division part plate electrode
405 plate electrode
406 transparent division part plate electrode

What is claimed is:

1. An optical semiconductor device that performs photoelectric conversion, comprising:
a semiconductor substrate that includes (i) a first conductivity-type semiconductor region, (ii) a second conductivity-type semiconductor region that is positioned on the first conductivity-type semiconductor region and has a light receiving surface, and (iii) a first conductivity-type contact region that penetrates, from an upper surface of the second conductivity-type semiconductor region, the second conductivity-type semiconductor region so as to be in contact with the first conductivity-type semiconductor region;
an electrode pair for drawing current obtained by performing photoelectric conversion of light incident on the light receiving surface, the electrode pair being composed of (i) a first electrode that is positioned on the first conductivity-type contact region and (ii) a second electrode that is positioned on the second conductivity-type semiconductor region so as to be separated from the first electrode;
an insulating film that is positioned on the second conductivity-type semiconductor region and in an area between the first electrode and the second electrode; and
a third electrode that is positioned on the insulating film.

2. The optical semiconductor device of claim 1, wherein
when the second electrode is a cathode electrode, voltage that is lower than voltage applied to the cathode electrode is applied to the third electrode, and
when the second electrode is an anode electrode, voltage that is higher than voltage applied to the anode electrode is applied to the third electrode.

3. The optical semiconductor device of claim 1, wherein
the insulating film is an oxide film.

4. The optical semiconductor device of claim 3, wherein
the insulating film is a LOCOS (Local Oxidation of Silicon) film or an STI (Shallow Trench Isolation).

5. The optical semiconductor device of claim 1, wherein
the insulating film is composed of two layers or more.

6. The optical semiconductor device of claim 1, wherein
the insulating film is a nitride film.

7. The optical semiconductor device of claim 1, wherein
the first electrode and at least part of the third electrode are integrally formed.

8. The optical semiconductor device of claim 1, wherein
the third electrode is composed of two layers or more that include a bottom electrode and a top electrode.

9. The optical semiconductor device of claim 1, wherein
a second conductivity-type contact region is positioned on the second conductivity-type semiconductor region so as to be in contact with the second electrode, and extends along the second conductivity-type semiconductor region to a position below the third electrode.

10. The optical semiconductor device of claim 1, wherein
the second electrode is positioned so as to surround the light receiving surface,
the third electrode is positioned so as to surround the second electrode, and
the first electrode is positioned so as to surround the third electrode.

11. The optical semiconductor device of claim 1, wherein
the third electrode is made of at least one type of metal or a metal compound.

12. The optical semiconductor device of claim 1, wherein
the third electrode is made of polycrystal silicon or amorphous silicon.

13. The optical semiconductor device of claim 1, wherein
the third electrode is made of a silicon compound.

14. The optical semiconductor device of claim 1 further comprising:
a division unit configured to divide the light receiving surface into a plurality of areas; and
a fourth electrode that is positioned on the division unit.

15. The optical semiconductor device of claim 14, wherein
the third electrode and the fourth electrode are electrically connected with each other.

16. The optical semiconductor device of claim 14, wherein
a width of the fourth electrode is greater than a width of the division unit, and
the fourth electrode is made of a material that transmits light and has conductivity.

17. The optical semiconductor device of claim 16, wherein
the fourth electrode is made of ITO (Indium Tin Oxide) or tin oxide.

18. The optical semiconductor device of claim 1 further comprising one or more electron elements positioned on the semiconductor substrate.
